(19) United States
(12) Patent Application Publication
(10) Pub. No.: US 2022/0231095 A1
(43) Pub. Date: Jul. 21, 2022

(54) ORGANIC LIGHT EMITTING DIODE DISPLAY

(71) Applicant: 3M INNOVATIVE PROPERTIES COMPANY, St. Paul, MN (US)

(72) Inventors: Nicholas C. ERICKSON, St. Paul, MN (US); Stephen M. MENKE, St. Paul, MN (US)

(21) Appl. No.: 17/609,618

(22) PCT Filed: May 7, 2020
(86) PCT No.: PCT/IB2020/054327

§ 371 Date: Nov. 8, 2021

Related U.S. Application Data
(60) Provisional application No. 62/846,835, filed on May 13, 2019.

(51) Int. Cl. H01L 27/32

(52) U.S. Cl. CPC H01L 27/3213; H01L 2251/308; H01L 51/5265; H01L 2251/558; H01L 2251/5315

(57) ABSTRACT

An organic light emitting diode (OLED) display is disclosed. The OLED display includes a first stack having a first emission layer and a first layer. The first emission layer emits red light, green light, or blue light. The OLED display includes a second stack having a second emission layer and a second layer. The second stack emits light of a different angular spectral distribution as that emitted by the first stack. Further, a thickness of the second layer is different from a thickness of the first layer such that light emitted by the first emission layer resonates within the first stack at a first degree and light emitted by the second emission layer resonates within the second stack at a second degree, the first degree being greater than the second degree.

### TECHNICAL FIELD

The present disclosure relates generally to organic light emitting diode (OLED) displays.

### BACKGROUND

A wide variety of OLED displays are known. Some OLED displays have a pixelated OLED display panel including an array of individually addressable OLED pixels or subpixels. Such pixelated OLED displays are becoming increasingly popular for use in various electronic devices such as for mobile phones, televisions, and similar end uses. Some OLED displays, referred to as “bottom emitting” OLED displays, emit light through a semi-transparent substrate on which the OLED display is fabricated. Others, referred to as “top emitting” OLED displays, emit light in the opposite direction, i.e., away from the substrate on which the OLED display is fabricated.

In various configurations of OLED displays, each of the red, green, and blue subpixels may exhibit color shifts as a function of viewing angle, especially when the OLED subpixels are optimized to achieve high axial efficiency. Thus, there is a tradeoff between the axial efficiency and the color shift of the subpixel. Commonly, axial efficiency is sacrificed to achieve lower color shift in the OLED display. However, such tradeoffs may result in lesser efficiency and non-uniform distribution of colors.

### SUMMARY

Generally, the present disclosure relates to organic light emitting diode (OLED) displays. The present disclosure may also relate to OLED displays with enhanced color uniformity and high axial efficiency.

In one embodiment of the present disclosure, the OLED display includes a pixelated OLED display panel including a plurality of pixels. Each pixel includes a plurality of subpixels, wherein each subpixel has a plurality of OLED layers. The OLED display includes a first reflective electrode and a second reflective electrode configured to reflect at least a portion of incident light. The OLED display further includes a first semi-reflective electrode and a second semi-reflective electrode disposed opposite to the first reflective electrode and the second reflective electrode, respectively. The first and second semi-reflective electrodes are configured to allow at least a portion of incident light to pass therethrough. The OLED display includes a first stack having a first emission layer disposed between the first reflective electrode and the first semi-reflective electrode. The first emission layer emits red light, green light, or blue light. The first stack includes a first layer disposed between the first emission layer and one of the first reflective electrode or the first semi-reflective electrode. The OLED display includes a second stack spaced apart from the first stack. The second stack has a second emission layer disposed between the second reflective electrode and the second semi-reflective electrode. The second stack emits light of a different angular spectral distribution as that emitted by the first stack. The second stack includes a second layer disposed between the second emission layer and one of the second reflective electrode or the second semi-reflective electrode. A thickness of the second layer is different from a thickness of the first layer such that light emitted by the first emission layer resonates within the first stack at a first degree and light emitted by the second emission layer resonates within the second stack at a second degree, the first degree being greater than the second degree.

In some embodiments, the first layer is a hole transport layer disposed between the first reflective electrode and the first emission layer. In some embodiments, the second layer is a hole transport layer disposed between the second reflective electrode and the second emission layer.

In some embodiments, the first layer is an electron transport layer disposed between the first semi-reflective electrode and the first emission layer. In some embodiments, the second layer is an electron transport layer disposed between the second semi-reflective electrode and the second emission layer.

In some embodiments, the thickness of the first layer is from about 95 nm to about 114 nm. In some embodiments, the thickness of the second layer is from about 115 nm to about 175 nm.

In some embodiments, the first emission layer emits blue light. In some embodiments, a ratio of the thickness of the second layer to the thickness of the first layer is from about 1.3 to about 1.6.

In some embodiments, the first emission layer emits green light. In some embodiments, the ratio of the thickness of the second layer to the thickness of the first layer is from about 1.25 to about 1.35.

In some embodiments, the first emission layer emits red light. In some embodiments, the ratio of the thickness of the second layer to the thickness of the first layer is from about 0.8 to about 1.25.

In some embodiments, the OLED display is of a top emission type. In some embodiments, the OLED display includes a driver provided for each of the first and the second stacks, wherein each driver operates independently.

### BRIEF DESCRIPTION OF THE DRAWINGS

The disclosure may be more completely understood in consideration of the following detailed description in connection with the following figures. The figures are not necessarily drawn to scale. Like numbers used in the figures refer to like components. However, it will be understood that the use of a number to refer to a component in a given figure is not intended to limit the component in another figure labeled with the same number.

FIGS. 1A and 1B are schematic cross-sectional views of an organic light emitting diode (OLED) display;

FIGS. 2A and 2B are schematic top views of an exemplary OLED display;

FIGS. 3A to 3D are exemplary plots illustrating the performance of blue light of a tuned blue subpixel;

FIGS. 4A to 4D are exemplary plots illustrating the performance of combined blue light of the tuned blue subpixel and a detuned blue subpixel;

FIG. 5 is a table listing exemplary values of various parameters to illustrate the performance of combined blue light of the tuned blue subpixel and the detuned blue subpixel;

FIGS. 6A to 6D are exemplary plots illustrating the performance of green light of a tuned green subpixel;

FIGS. 7A to 7D are exemplary plots illustrating the performance of combined green light of the tuned green subpixel and a detuned green subpixel;

FIG. 8 is a table listing exemplary values of various parameters to illustrate the performance of combined green light of the tuned green subpixel and the detuned green subpixel;

FIGS. 9A to 9D are exemplary plots illustrating the performance of red light of a tuned red subpixel;

FIGS. 10A to 10D are exemplary plots illustrating the performance of combined red light of the tuned red subpixel and a detuned red subpixel; and

FIG. 11 is a table listing exemplary values of various parameters to illustrate the performance of combined red light of the tuned red subpixel and the detuned red subpixel.

### DETAILED DESCRIPTION

In the following description, reference is made to the accompanying figures that form a part thereof and in which various embodiments are shown by way of illustration. It is to be understood that other embodiments are contemplated and may be made without departing from the scope or spirit of the present disclosure. The following detailed description, therefore, is not to be taken in a limiting sense.

The present disclosure relates to an organic light emitting diode (OLED) display having a first stack and a second stack of layers. The second stack emits light of a different angular spectral distribution as compared to that of the first stack. This is achieved by designing the first and second stacks such that light emitted by the first stack resonates and light emitted by the second stack does not resonate. Specifically, the first and the second stacks include a first layer and a second layer, respectively, wherein a thickness of the second layer is different from that of the first layer to achieve resonance in the first stack and non-resonance in the second stack. The combination of light emitted from the first and the second stacks may result in lower color shift and higher axial efficiency. The OLED display can be used in various devices, such as mobile phones, televisions, and so forth.

The term “resonate”, as used herein, refers to constructive interference of light within a subpixel of the OLED display. Specifically, the subpixel may be designed such that, for a particular wavelength of light emitted within the stack, distance between the electrodes may be such that light beams constructively interfere with each other resulting in enhanced light intensity. The term “does not resonate”, as used herein, means that light within a stack does not constructively interfere and light intensity does not increase.

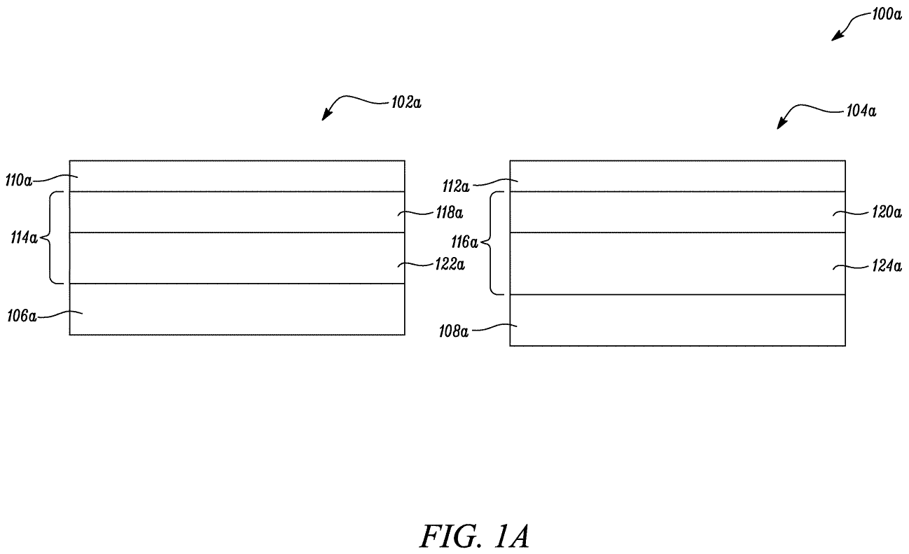

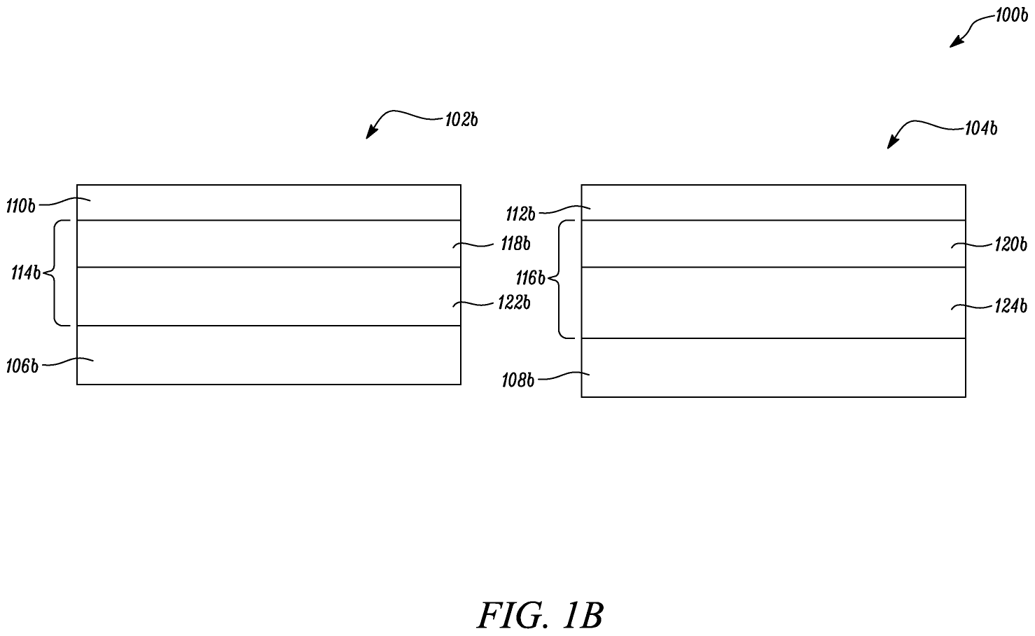

FIG. 1A shows a schematic cross-sectional view of an organic light emitting diode (OLED) display 100a. The OLED display 100a includes a pixelated OLED display panel (not shown) including a plurality of pixels. The pixels may be repeatedly arranged in columns and rows. Each pixel has a plurality of subpixels. In one embodiment, each pixel includes a red (R) subpixel, a green (G) subpixel, and a blue (B) subpixel. Each subpixel has a plurality of OLED layers.

Referring to FIG. 1A, the OLED display 100a includes a first subpixel 102a and a second subpixel 104a. The first and second subpixels 102a, 104a include a first reflective electrode 106a and a second reflective electrode 108a, respectively, configured to reflect at least a portion of incident light. For example, the first reflective electrode 106a and/or the second reflective electrode 108a may be configured to reflect at least about 80%, at least about 85%, at least about 90%, at least about 92%, or at least about 95% of incident light. The OLED display 100a further includes a first semi-reflective electrode 110a disposed opposite to the first reflective electrode 106a and a second semi-reflective electrode 112a disposed opposite to the second reflective electrode 108a. The first and second semi-reflective electrodes 110a, 112a are configured to allow at least a portion of incident light to pass therethrough. For example, the first semi-reflective electrode 110a and/or the second semi-reflective electrode 112a may be configured to allow at least about 50%, or at least about 60%, or at least about 70% of incident light to pass therethrough. In some embodiments, each of the first and second reflective electrodes 106a, 108a may be considered as an anode and each of the first and second semi-reflective electrodes 110a, 112a may be considered as a cathode.

In some embodiments, the first and second reflective electrodes 106a, 108a and the first and second semi-reflective electrodes 110a, 112a are formed using conducting materials, such as metals, alloys, metallic compounds, conductive metal oxides, conductive dispersions, and conductive polymers, including, for example, gold, silver, nickel, chromium, barium, platinum, palladium, aluminum, calcium, titanium, indium tin oxide (ITO), fluorine tin oxide (FTO), antimony tin oxide (ATO), indium zinc oxide (IZO), poly(3,4-ethylenedioxythiophene)/poly(styrene sulfonate), polyaniline, other conducting polymers, alloys thereof, or combinations thereof. The first and second reflective electrodes 106a, 108a and the first and second semi-reflective electrodes 110a, 112a can be single layers of conducting materials or can include multiple layers of conducting materials.

The material coating the substrate of the first and second reflective electrodes 106a, 108a may be electrically conductive. In some embodiments, a material for coating the first and second reflective electrodes 106a, 108a is indium tin oxide (ITO). In addition to ITO, suitable materials may include indium oxide, fluorine tin oxide (FTO), zinc oxide, indium zinc oxide (IZO), vanadium oxide, zinc-tin oxide, gold, platinum, palladium, aluminum, silver, other high work function metals, and combinations thereof. In one embodiment, the first and second reflective electrodes 106a, 108a have an optically thick metallic layer of aluminum (Al) coated with a thin layer of indium tin oxide (ITO). The first and second reflective electrodes 106a, 108a may have thicknesses in the order of about 100 nanometers (nm). However, the thicknesses of the first reflective electrode 106a and/or the second reflective electrode 108a may be varied as per application requirements.

The first and second semi-reflective electrodes 110a, 112a may be formed using low work function metals, such as aluminum, barium, calcium, samarium, magnesium, silver, magnesium/silver alloys, lithium, ytterbium, and calcium/magnesium alloys. In one embodiment, the first and second semi-reflective electrodes 110a, 112a may be made of magnesium (Mg) and silver (Ag). As an example, the composition of the first and second semi-reflective electrodes 110a, 112a may be about 90% Mg by weight and about 10% Ag by weight. The first and second semi-reflective electrodes 110a, 112a may have thicknesses of the order of about 10 nm. However, the thicknesses of the first semi-reflective electrode 110a and/or the second semi-reflective electrode 112a may be varied as per application requirements.

The first and second subpixels 102a, 104a include a first stack 114a and a second stack 116a, respectively. The second stack 116a is spaced apart from the first stack 114a. The first and second stacks 114a, 116a have one or more layers. The first stack 114a includes a first emission layer 118a disposed between the first reflective electrode 106a and the first semi-reflective electrode 110a. The second stack 116a includes a second emission layer 120a disposed between the second reflective electrode 108a and the second semi-reflective electrode 112a. The first emission layer 118a may include one or more organic layers tailored to emit light of a desired wavelength in response to an electric voltage applied between the first reflective electrode 106a and the first semi-reflective electrode 110a.

In the illustrated embodiment, the OLED display 100a is a top emitting type OLED display wherein the first reflective electrode 106a is disposed below the first emission layer 118a and light is extracted from top via the first semi-reflective electrode 110a. In alternative embodiments, the OLED display 100a may be arranged in other configurations, such as bottom emitting type or dual emitting type. In other words, embodiments of the present disclosure are not limited by the emission type of the OLED display 100a.

The first and second emission layers 118a, 120a may include a light-emitting material, which is an electroluminescent material that emits light when electrically activated. In one embodiment, the first and second emission layers 118a, 120a are configured to emit red light, green light, or blue light. Red, green, and blue light typically have wavelengths in the range of about 600 to about 700 nm, about 500 to about 560 nm, and about 430 to about 490 nm, respectively. In other embodiments, the first and second emission layers 118a, 120a may be configured to emit light of other colors such as, but not limited to, cyan, magenta, yellow, and orange. In one embodiment, the first and second emission layers 118a, 120a may have a thicknesses of about 20 nm.

The first and second emission layers 118a, 120a may include one or more light emitting polymers (LEP) or other light-emitting materials, such as small molecule (SM) light-emitting compounds. LEP materials may be conjugated polymeric or oligomeric molecules that have sufficient film-forming properties for solution processing. As used herein, “conjugated polymers or oligomeric molecules” refer to polymers or oligomers having a delocalized π-electron system along the polymer backbone. Such polymers or oligomers are semiconducting and can support positive and negative charge carriers along the polymeric or oligomeric chain. Exemplary LEP materials include poly(phenylenevinylenes), poly(para-phenylenes), polyfluorenes, and co-polymers or blends thereof. Suitable LEPs can also be doped with a small molecule light-emitting compound, dispersed with fluorescent or phosphorescent dyes or photoluminescent materials, blended with active or non-active materials, dispersed with active or non-active materials, and so forth.

SM materials are generally non-polymeric, organic, or organometallic molecular materials that can be used in OLED displays and devices as emitter materials, charge transport materials, dopants in emission layers (e.g., to control the emitted color) or charge transport layers, and the like. Exemplary SM materials include N,N′-bis(3-methylphenyl)-N,N′-diphenylbenzidine (TPD) and metal chelate compounds such as tris(8-hydroxyquinoline)aluminum (Alq3) and biphenylato bis(8-hydroxyquinolato)aluminum (BAlq).

In one embodiment, the first stack 114a is disposed between the first reflective electrode 106a and the first semi-reflective electrode 110a. The first stack 114a includes a first layer 122a disposed between the first emission layer 118a and the first reflective electrode 106a. The second stack 116a is disposed between the second reflective electrode 108a and the second semi-reflective electrode 112a. The second stack 116a includes a second layer 124a disposed between the second emission layer 120a and the second reflective electrode 108a. The first and second layers 122a, 124a may be a hole transport layer, a hole injection layer, an electron blocking layer, a buffer layer, or a combination thereof. The first and second emission layers 118a, 120a may be an electron transport layer, an electron injection layer, a hole blocking layer, an emissive layer, a buffer layer, or a combination thereof.

In one embodiment, the first layer 122a is a hole transport layer disposed between the first reflective electrode 106a and the first emission layer 118a. Within the first stack 114a, the hole transport layer may facilitate the injection of holes from the first reflective electrode 106a and their migration towards a recombination zone within the first emission layer 118a. The hole transport layer may further act as a barrier for the passage of electrons to the first reflective electrode 106a. Further, the second layer 124a may be a hole transport layer disposed between the second reflective electrode 108a and the second emission layer 120a. The hole transport layer can include, for example, a diamine derivative such as N,N′-bis(3-methylphenyl)-N,N′-bis(phenyl)benzidine (TPD), N,N′-bis(2-naphthyl)-N,N′-bis(phenyl)benzidine (beta-NPB), N,N′-bis(1-naphthyl)-N,N′-bis(phenyl)benzidine (NPB), or the like; or a triarylamine derivative such as, 4,4′,4″-tris(N,N-diphenylamino)triphenylamine (TDATA), 4,4′,4″-tris(N-3-methylphenyl-N-phenylamino)triphenylamine (MTDATA), 4,4′,4″-tri(N-phenoxazinyl)triphenylamine (TPOTA), 1,3,5-tris(4-diphenylaminophenyl)benzene (TDAPB), or the like.

FIG. 1B shows a schematic cross-sectional view of an OLED display 100b in another embodiment of the present disclosure. The OLED display 100b has similar components as the OLED display 100a. As shown in FIG. 1B, the OLED display 100b includes a first subpixel 102b and a second subpixel 104b. The first and second subpixels 102b, 104b include a first reflective electrode 106b and a second reflective electrode 108b, respectively, configured to reflect at least a portion of incident light. The OLED display 100b further includes a first semi-reflective electrode 110b disposed opposite to the first reflective electrode 106b and a second semi-reflective electrode 112b disposed opposite to the second reflective electrode 108b. The first and second semi-reflective electrodes 110b, 112b are configured to allow at least a portion of incident light to pass therethrough.

The first subpixel 102b includes a first stack 114b which is disposed between the first reflective electrode 106b and the first semi-reflective electrode 110b. The first stack 114b includes a first layer 118b disposed between a first emission layer 122b and the first semi-reflective electrode 110b. The second subpixel 104b includes a second stack 116b which is disposed between the second reflective electrode 108b and the second semi-reflective electrode 112b. The second stack 116b includes a second layer 120b disposed between a second emission layer 124b and the second semi-reflective electrode 112b. The first and second layers 118b, 120b may be an electron transport layer, an electron injection layer, a hole blocking layer, a buffer layer, or a combination thereof. The first and second emission layers 122b, 124b may be a hole transport layer, a hole injection layer, an electron blocking layer, an emissive layer, a buffer layer, or a combination thereof.

Within the first stack 114b, the electron transport layer may facilitate the injection of electrons from the first semi-reflective electrode 110b and their migration towards the recombination zone within the first emission layer 122b. The electron transport layer may further act as a barrier for the passage of holes to the first semi-reflective electrode 110b. Further, the second layer 120b may be an electron transport layer disposed between the second semi-reflective electrode 112b and the second emission layer 124b.

The electron transport layer can be formed using the organometallic compound, such as tris(8-hydroxyquinolato) aluminum (Alq3) and biphenylato bis(8-hydroxyquinolato)aluminum (BAlq). Other examples of electron transport materials useful in electron transport layer include 1,3-bis[5-(4-(1,1-dimethylethyl)phenyl)-1,3,4-oxadiazol-2-yl]benzene; 2-(biphenyl-4-yl)-5-(4-(1,1-dimethylethyl)phenyl)-1,3,4-oxadiazole; 9,10-di(2-naphthyl)anthracene (ADN); 2-(4-biphenyl)-5-(4-t-butylphenyl)-1,3,4-oxadiazole; or 3-(4-biphenylyl)-4-phenyl-5-(4-tert-butylphenyl)-1,2,4-triazole (TAZ).

In the subpixel 102a, light emitted by the first emission layer 118a forms a micro cavity while reciprocating between the first reflective electrode 106a and the first semi-reflective electrode 110a. Similar micro cavities are also formed in the subpixels 104a, 102b, and 104b. The first stack 114a may be designed to exhibit resonance phenomenon wherein light beams may constructively interfere with each other. As a result, an optical intensity of light extracted from the first stack 114a may be enhanced. The subpixel 102a may be referred to as the tuned subpixel 102a in various embodiments of the present disclosure. A thickness of the first layer 122a may be designed such that light emitted by the first emission layer 118a resonates within the first stack 114a. In one embodiment, the thickness of the first layer 122a is from about 95 nm to about 114 nm.

In the subpixel 104a, the second stack 116a may be designed such that light beams do not constructively interfere with each other and resonance does not take place. Specifically, a thickness of the second layer 124a may be designed such that light emitted by the second emission layer 120a does not resonate within the second stack 116a. The subpixel 104a may be referred to as the detuned subpixel 104a in various embodiments of the present disclosure. The second stack 116a emits light of a different angular spectral distribution as compared to that of the first stack 114a. For example, light emitted by the second stack 116a may have a different distribution of brightness (or luminance) vs viewing angle or wavelength vs viewing angle as compared to that of the first stack 114a.

In some implementations, the light emitted by the first emission layer 118a resonates within the first stack 114a at a first degree and light emitted by the second emission layer 120a resonates within the second stack 116a at a second degree. In some implementations the first degree is greater than the second degree.

In some implementations, the light emitted by the first emission layer 118b resonates within the first stack 114b at a first degree and light emitted by the second emission layer 120b resonates within the second stack 116b at a second degree. In some implementations the first degree is greater than the second degree.

Referring to FIG. 1A, the thickness of the second layer 124a is different from the thickness of the first layer 122a. In one embodiment, the thickness of the second layer 124a is from about 115 nm to about 175 nm and the thickness of the first layer 122a is from about 95 nm to about 114 nm. Similarly, in the illustrated embodiment of FIG. 1B, the thickness of the second layer 120b is different from the thickness of the first layer 118b.

The thicknesses of the first layer 122a and second layer 124a may depend on the color of light emitted by the first emission layers 118a and second emission layers 120a respectively. For instance, when the first and second emission layers 118a, 120a emit blue light, a ratio of the thickness of the second layer 124a to the thickness of the first layer 122a is from about 1.3 to about 1.6. Similarly, when the first and second emission layers 118a, 120a emit green light, a ratio of the thickness of the second layer 124a to the thickness of the first layer 122a is from about 1.25 to about 1.35. Further, when the first and second emission layers 118a, 120a emit red light, a ratio of the thickness of the second layer 124a to the thickness of the first layer 122a is from about 0.8 to about 1.25.

A combination of the detuned subpixel 104a and the tuned subpixel 102a may result in improved color uniformity and lower color-shift. For example, when the first stack 114a emits blue light, the light from the detuned subpixel 104a mixes with the blue light from the tuned subpixel 102a and the resultant blue light has better axial efficiency and lower color shift as compared to that from only the tuned subpixel 102a. Thus, color performance of the OLED display 100a is improved.

In some embodiments, the OLED display 100a includes a driver for each of the subpixels 102a, 104a. The driver may be configured to supply the electrical current required to drive the subpixels. In one embodiment, each of the drivers operate independently. The electrical current provided to the tuned subpixel 102a and the electrical current provided to the detuned subpixel 104a may be controlled independently of each other to achieve desired color shift and axial efficiency. Thus, the detuned subpixel 104a may provide an extra degree of freedom for controlling the OLED display 100a as compared to a standard OLED display.

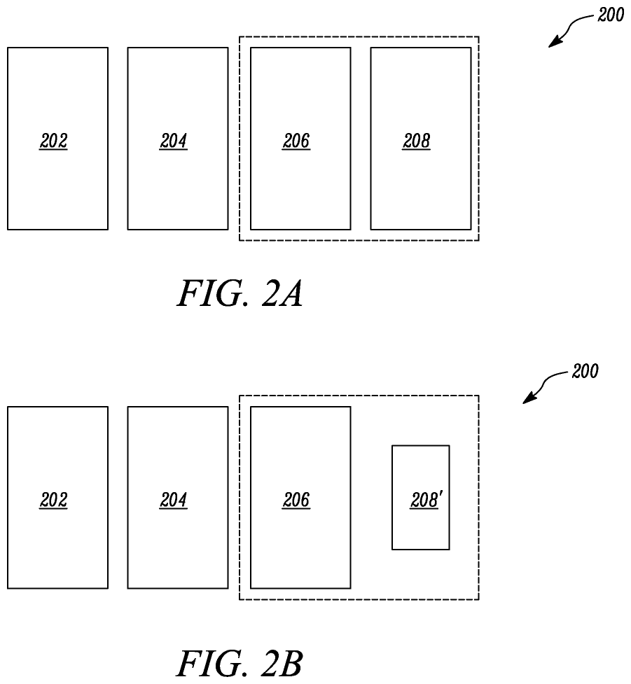

FIGS. 2A and 2B illustrate top views of the OLED display 200. The OLED display 200 includes a red (R) subpixel 202, a green (G) subpixel 204, a blue (B) subpixel 206, and a detuned subpixel 208. In the illustrated embodiment, the detuned subpixel 208 is associated with the blue subpixel 206. The blue subpixel 206 is designed such that it exhibits resonance (tuned) and the detuned subpixel 208 is designed such that it does not exhibit resonance (detuned). Specifically, the thicknesses of the layers of the subpixels 206, 208 may be selected such that the blue subpixel 206 is tuned and the detuned subpixel 208 is detuned.

Referring to FIG. 2A, the blue subpixel 206 and the detuned subpixel 208 have similar cross-sectional dimensions when viewed from top. However, in other embodiments, the detuned subpixel 208′ may have smaller cross-sectional dimensions as compared to that of the blue subpixel 206 when viewed from top, as shown in FIG. 2B. The configurations shown in FIGS. 2A, 2B can be referred to as RGBB′ configuration having two blue subpixels (tuned (B) and detuned (B′)).

In various embodiments, the detuned subpixel 208 may be associated with the red subpixel 202 or the green subpixel 204. For example, the OLED display 200 may have RR′GB or RGG′B configurations. Furthermore, the OLED display 200 may include a plurality of detuned subpixels 208. For example, the OLED display 200 may include two detuned subpixels resulting in RR′GG′B, RR′GBB′, or RGG′BB′ configurations. In one embodiment, the OLED display 200 includes three detuned subpixels 208, one each for red subpixel 202, green subpixel 204, and blue subpixel 206 resulting in RR′GG′BB′ configuration. The aforementioned configurations may be required to simultaneously optimize the performance of multiple colors in the OLED display 200. Use of red, green, and blue color light in various embodiments of the present disclosure has been exemplary and it should be understood that light of other colors such as, but not limited to, cyan, magenta, yellow, and orange may also be used.

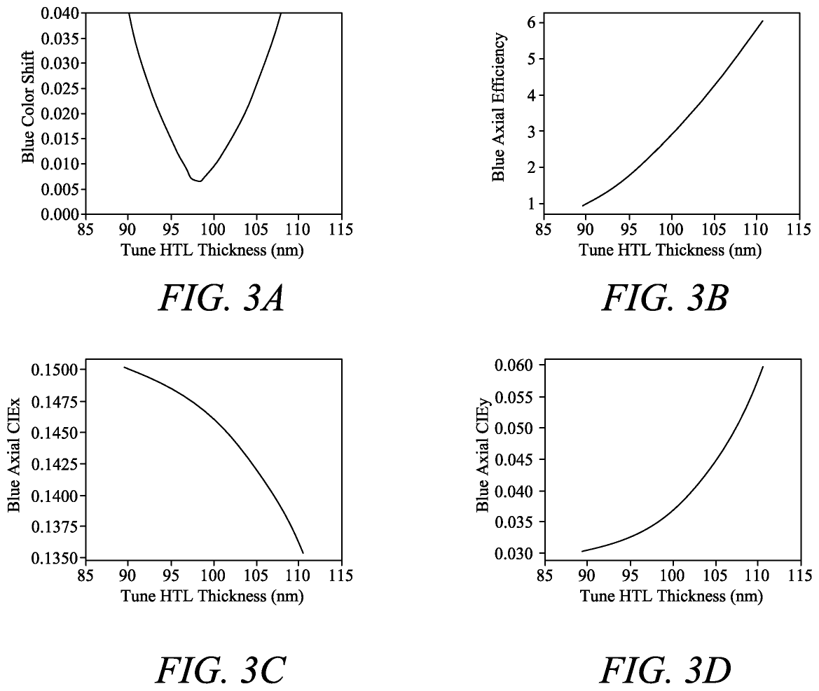

FIGS. 3A to 3D are exemplary plots illustrating the performance of blue light of the tuned blue subpixel. FIG. 3A shows the relationship between blue color shift and the thickness of the hole transport layer (HTL) layer of the tuned blue subpixel. FIG. 3B shows the relationship between blue axial efficiency and the thickness of the HTL layer of the tuned blue subpixel. FIGS. 3A and 3B show that the blue axial efficiency increases with the tuned HTL thickness and the blue color shift also increases with the tuned HTL thickness. Thus, it is difficult to achieve higher axial efficiency without compromising on color shift. FIGS. 3C and 3D show the relationships between chromaticity coordinates (CIEx, CIEy) and the thickness of the HTL layer of the tuned blue subpixel.

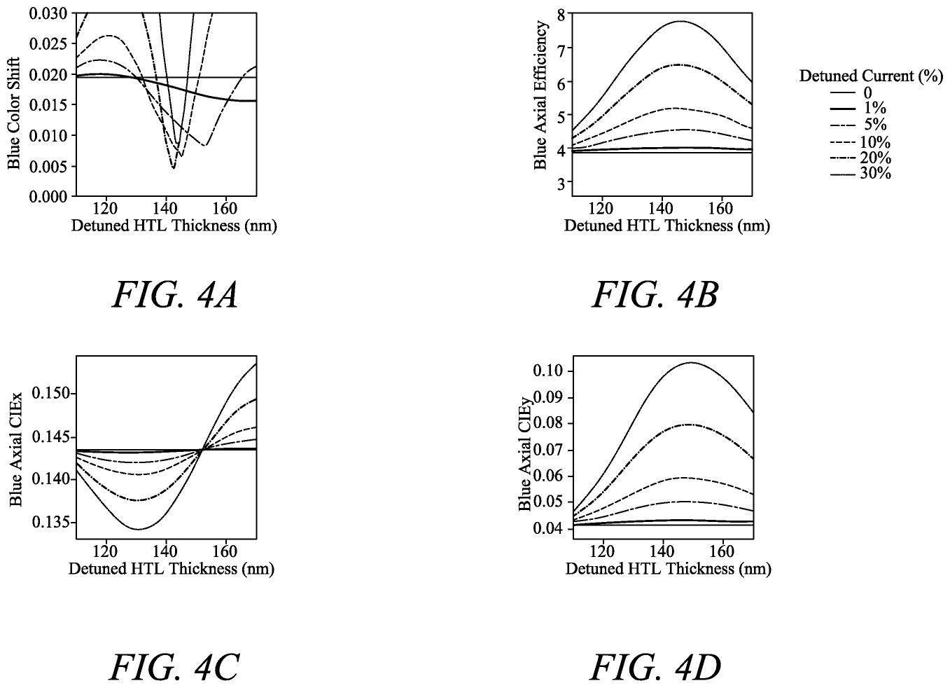

FIGS. 4A to 4D are exemplary plots illustrating the performance of combined blue light of the tuned blue subpixel and the detuned blue subpixel. In these examples, the thickness of the HTL layer of the tuned subpixel is about 103 nm. Detuned current is defined as the percentage ratio of the current applied to the detuned subpixel and the total current applied to tuned and detuned subpixels. FIG. 4A shows the relationship between blue color shift and the thickness of the HTL layer of the detuned blue subpixel for different values of detuned current. FIG. 4B shows the relationship between total blue axial efficiency and the thickness of the HTL layer of the detuned blue subpixel for different values of detuned current. FIGS. 4A and 4B show that for a detuned HTL thickness of about 140 nm and a detuned current of 30%, it is possible to obtain a total blue axial efficiency of about 7.8 and a total blue color shift of about 0.012. Thus, higher axial efficiency and lower color shift can be achieved using the combination of the tuned blue subpixel and the detuned blue subpixel. FIGS. 4C and 4D show the relationships between chromaticity coordinates (CIEx, CIEy) and the thickness of the HTL layer of the detuned blue subpixel for different values of detuned current.

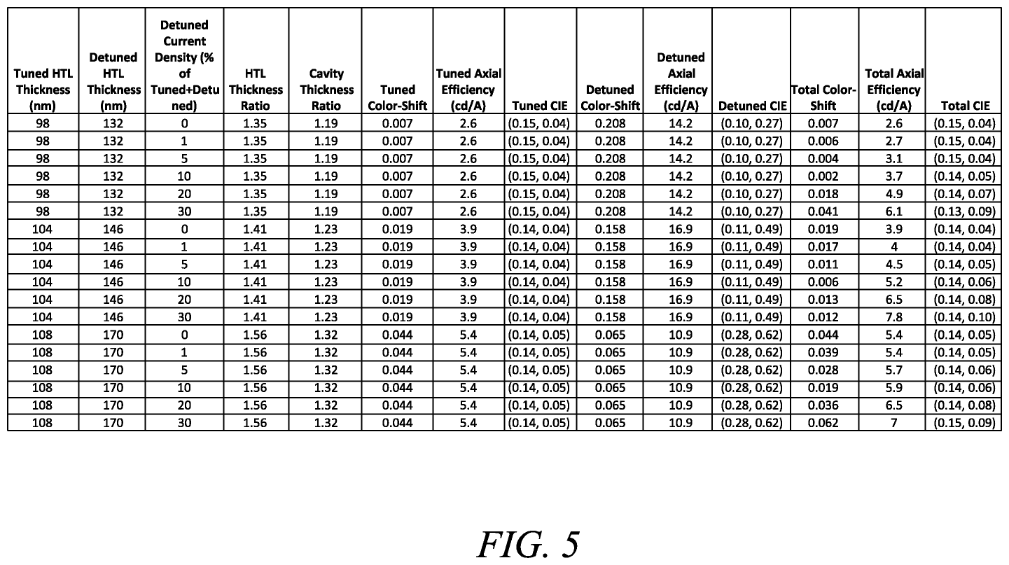

FIG. 5 is a table listing exemplary values of various parameters to illustrate the performance of combined blue light of the tuned blue subpixel and the detuned blue subpixel. For example, when the tuned HTL thickness is about 104 nm, the detuned HTL thickness is about 146 nm, and the detuned current is about 10%, the combination of the tuned blue subpixel and the detuned blue subpixel results in a blue color shift of about 0.06 and a total axial efficiency of about 5.2. Thus, it is possible to achieve lower blue color shifts without significantly degrading the axial efficiency.

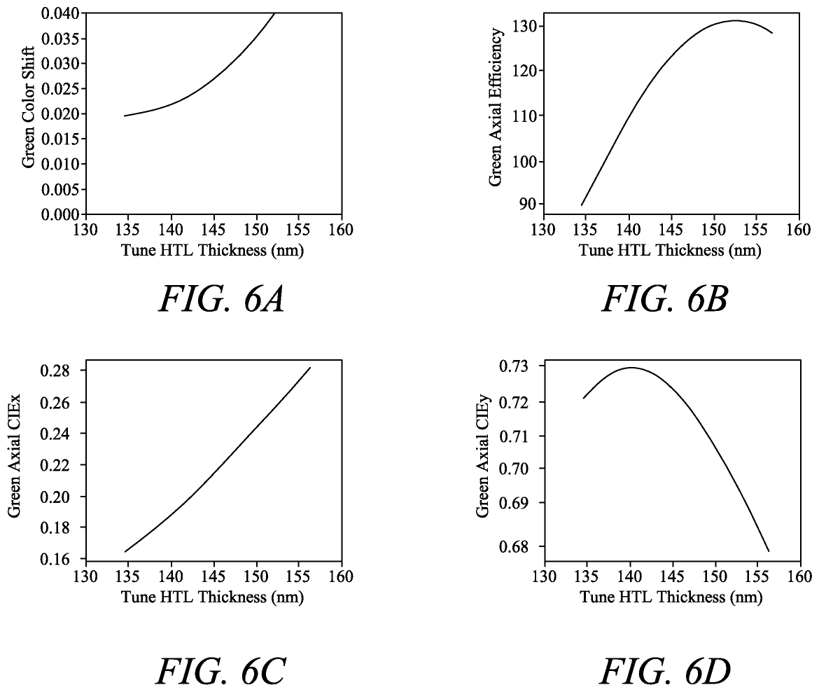

FIGS. 6A to 6D are exemplary plots illustrating the performance of green light of the tuned green subpixel. FIG. 6A shows the relationship between green color shift and the thickness of the HTL layer of the tuned green subpixel. FIG. 6B shows the relationship between green axial efficiency and the thickness of the HTL layer of the tuned green subpixel. FIGS. 6C and 6D show the relationships between chromaticity coordinates (CIEx, CIEy) and the thickness of the HTL layer of the tuned green subpixel.

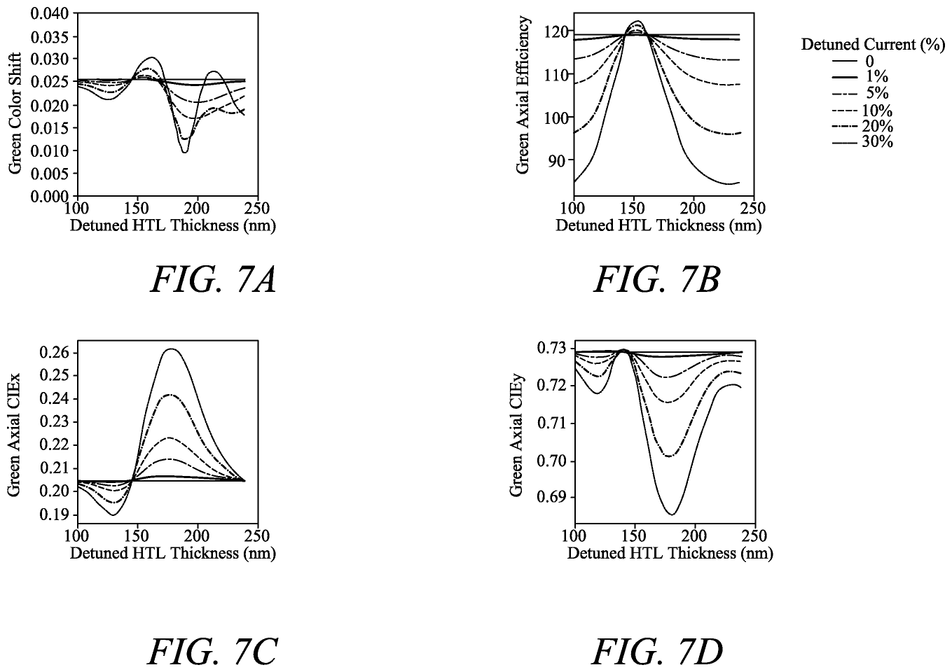

FIGS. 7A to 7D are exemplary plots illustrating the performance of combined green light of the tuned green subpixel and detuned green subpixel. In these examples, the thickness of the HTL layer of the tuned green subpixel is about 143 nm. FIG. 7A shows the relationship between green color shift and the thickness of the HTL layer of the detuned green subpixel for different values of detuned current. FIG. 7B shows the relationship between total green axial efficiency and the thickness of the HTL layer of the detuned green subpixel for different values of detuned current. FIGS. 7A and 7B show that for a detuned HTL thickness of about 194 nm and a detuned current of 5%, it is possible to obtain a total green axial efficiency of about 114.3 and a total green color shift of about 0.021. Thus, higher axial efficiency and lower color shift can be achieved using the combination of the tuned green subpixel and the detuned green subpixel. FIGS. 7C and 7D show the relationships between chromaticity coordinates (CIEx, CIEy) and the thickness of the HTL layer of the detuned green subpixel for different values of detuned current.

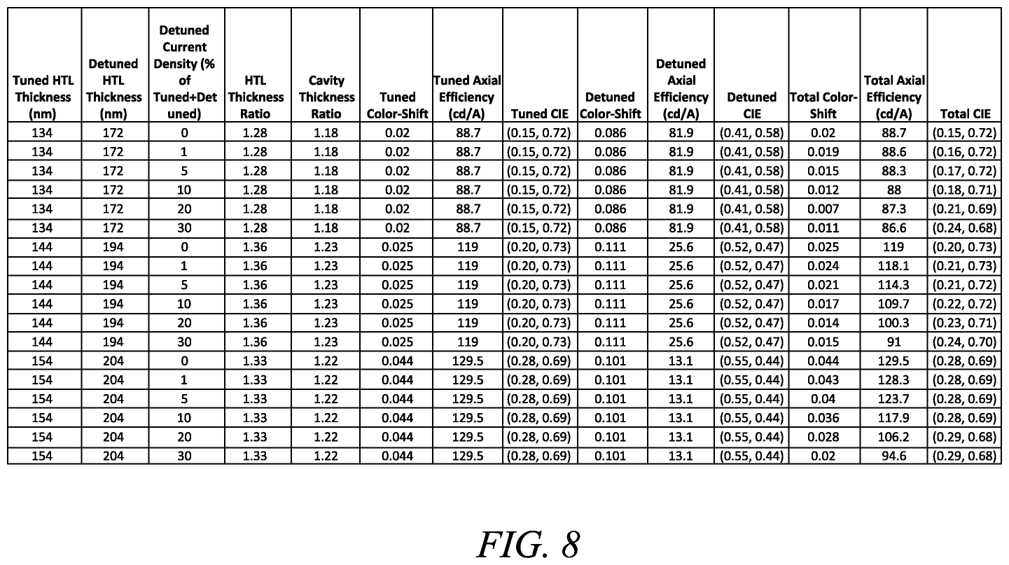

FIG. 8 is a table listing exemplary values of various parameters to illustrate the performance of combined green light of the tuned green subpixel and detuned green subpixel. For example, when the tuned HTL thickness is about 144 nm, the detuned HTL thickness is about 194 nm, and the detuned current is about 10%, the combination of the tuned green subpixel and the detuned green subpixel results in a green color shift of about 0.017 and a total axial efficiency of about 109.7. Thus, it is possible to achieve lower green color shifts without significantly degrading the axial efficiency.

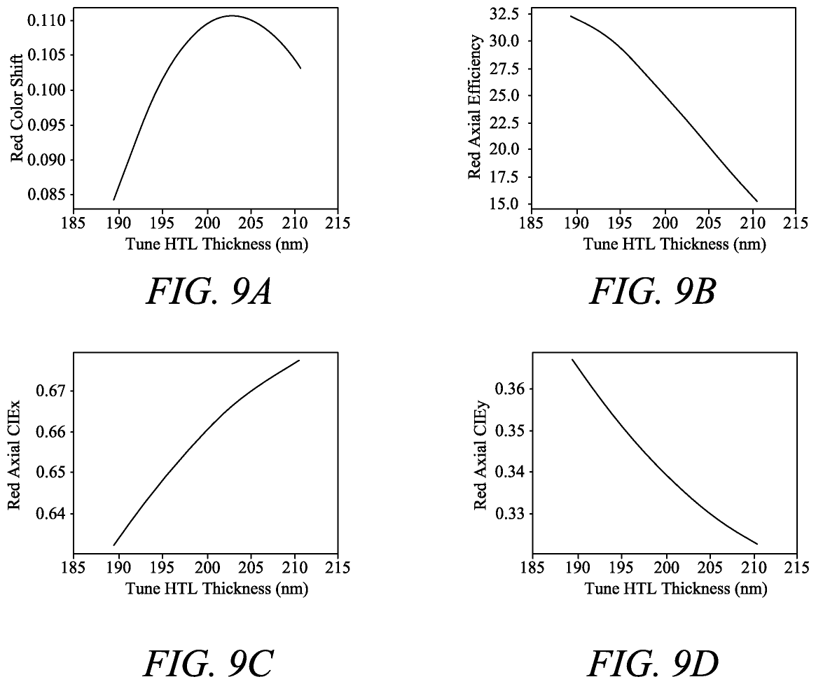

FIGS. 9A to 9D are exemplary plots illustrating the performance of red light of the tuned red subpixel. FIG. 9A shows the relationship between red color shift and the thickness of the HTL layer of the tuned red subpixel. FIG. 9B shows the relationship between red axial efficiency and the thickness of the HTL layer of the tuned red subpixel. FIGS. 9C and 9D show the relationships between chromaticity coordinates (CIEx, CIEy) and the thickness of the HTL layer of the tuned red subpixel.

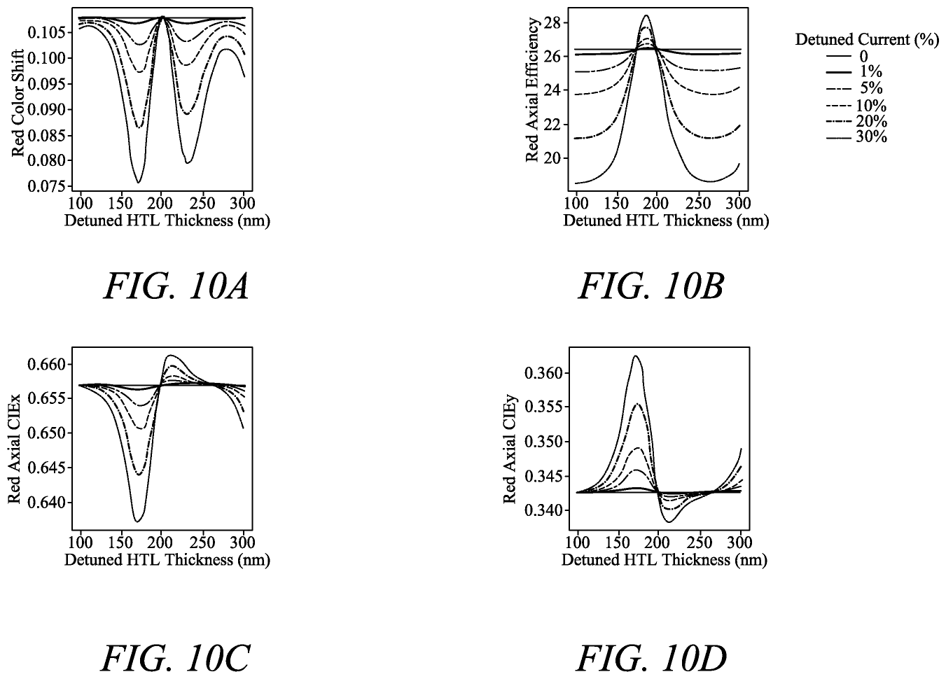

FIGS. 10A to 10D are exemplary plots illustrating the performance of combined red light of the tuned red subpixel and the detuned red subpixel. In these examples, the thickness of the HTL layer of the tuned red subpixel is about 198 nm. FIG. 10A shows the relationship between red color shift and the thickness of the HTL layer of the detuned red subpixel for different values of detuned current. FIG. 10B shows the relationship between total red axial efficiency and the thickness of the HTL layer of the detuned red subpixel for different values of detuned current. FIGS. 10A and 10B show that for a detuned HTL thickness of about 230 nm and a detuned current of 1%, it is possible to obtain a total red axial efficiency of about 32 and a total red color shift of about 0.083. Thus, higher axial efficiency and lower color shift can be achieved using the combination of the tuned red subpixel and the detuned red subpixel. FIGS. 10C and 10D show the relationships between chromaticity coordinates (CIEx, CIEy) and the thickness of the HTL layer of the detuned red subpixel for different values of detuned current.

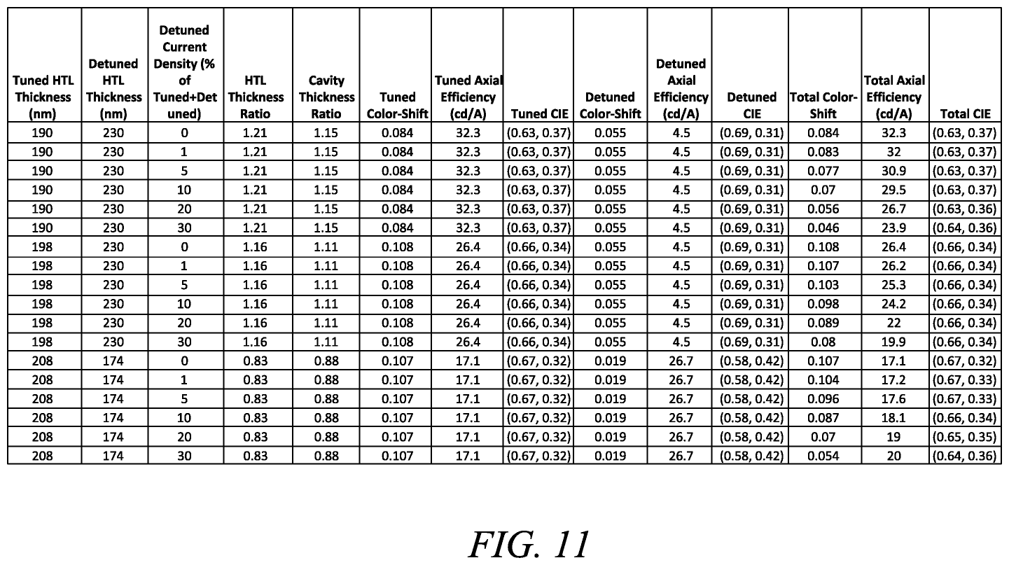

FIG. 11 is a table listing exemplary values of various parameters to illustrate the performance of combined red light of the tuned red subpixel and the detuned red subpixel. For example, when the tuned HTL thickness is about 190 nm, the detuned HTL thickness is about 230 nm, and the detuned current is about 20%, the combination of the tuned red subpixel and the detuned red subpixel results in a red color shift of about 0.056 and a total axial efficiency of about 26.7. Thus, it is possible to achieve lower red color shifts without significantly degrading the axial efficiency.

Unless otherwise indicated, all numbers expressing feature sizes, amounts, and physical properties used in the specification and claims are to be understood as being modified by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. An organic light emitting diode (OLED) display, comprising:
a pixelated OLED display panel including a plurality of pixels, each pixel comprising a plurality of subpixels, each subpixel comprising a plurality of OLED layers;
a first reflective electrode configured to reflect at least a portion of incident light;
a first semi-reflective electrode disposed opposite to the first reflective electrode, the first semi-reflective electrode configured to allow at least a portion of incident light to pass therethrough;
a second reflective electrode configured to reflect at least a portion of incident light;
a second semi-reflective electrode disposed opposite to the second reflective electrode, the second semi-reflective electrode configured to allow at least a portion of incident light to pass therethrough;
a first stack comprising:
a first emission layer disposed between the first reflective electrode and the first semi-reflective electrode, wherein the first emission layer emits red light, green light, or blue light; and
a first layer disposed between the first emission layer and one of the first reflective electrode or the first semi-reflective electrode; and
a second stack spaced apart from the first stack, the second stack comprising:
a second emission layer disposed between the second reflective electrode and the second semi-reflective electrode, wherein the second stack emits light of a different angular spectral distribution as that emitted by the first stack; and
a second layer disposed between the second emission layer and one of the second reflective electrode or the second semi-reflective electrode, wherein a thickness of the second layer is different from a thickness of the first layer such that light emitted by the first emission layer resonates within the first stack at a first degree and light emitted by the second emission layer resonates within the second stack at a second degree, the first degree being greater than the second degree.

2. The OLED display of claim 1, wherein the first layer is a hole transport layer disposed between the first reflective electrode and the first emission layer.

3. The OLED display of claim 1, wherein the second layer is a hole transport layer disposed between the second reflective electrode and the second emission layer.

4. The OLED display of claim 1, wherein the thickness of the second layer is from about 115 nm to about 175 nm.

5. The OLED display of claim 1, wherein the thickness of the first layer is from about 95 nm to about 114 nm.

6. The OLED display of claim 1, wherein the first emission layer emits blue light.

7. The OLED display of claim 6, wherein a ratio of the thickness of the second layer to the thickness of the first layer is from about 1.3 to about 1.6.

8. The OLED display of claim 1, wherein the first emission layer emits green light.

9. The OLED display of claim 8, wherein a ratio of the thickness of the second layer to the thickness of the first layer is from about 1.25 to about 1.35.

10. The OLED display of claim 1, wherein the first emission layer emits red light.

11. The OLED display of claim 10, wherein a ratio of the thickness of the second layer to the thickness of the first layer is from about 0.8 to about 1.25.

12. The OLED display of claim 1, wherein the second layer is an electron transport layer disposed between the second semi-reflective electrode and the second emission layer.

13. The OLED display of claim 1, wherein the first layer is an electron transport layer disposed between the first semi-reflective electrode and the first emission layer.

14. The OLED display of claim 1, wherein the OLED display is of a top emission type.

15. The OLED display of claim 1, further comprising a driver provided for each of the first and the second stacks, wherein each driver operates independently.
